(19) United States
(12) Patent Application Publication
(10) Pub. No.: US 2020/0091082 A1
(43) Pub. Date: Mar. 19, 2020

(54) METALLIC CARBON QUANTUM WIRE FROM SELF-ASSEMBLED ALPHALTENE

(71) Applicants: Eva M. Deemer, El Paso, TX (US); Manuel Alvarado, El Paso, TX (US); Miriam Montana, El Paso, TX (US); Russell R. Chianelli, El Paso, TX (US)

(72) Inventors: Eva M. Deemer, El Paso, TX (US); Manuel Alvarado, El Paso, TX (US); Miriam Montana, El Paso, TX (US); Russell R. Chianelli, El Paso, TX (US)

(73) Assignee: THE BOARD OF REGENTS OF THE UNIVERSITY OF TEXAS SYSTEM, Austin, TX (US)

(21) Appl. No.: 16/558,740

(22) Filed: Sep. 3, 2019

Related U.S. Application Data
(60) Provisional application No. 62/730,729, filed on Sep. 13, 2018.

(51) Int. Cl. H01L 23/532; H01L 23/522; H01L 21/288; H01L 21/768; C01B 32/184

(52) U.S. Cl. CPC H01L 23/53276; H01L 23/5226; H01L 21/288; B82Y 30/00; C01B 32/184; H01L 2221/1094; H01L 21/76883

(57) ABSTRACT

The present disclosure is related to a method of fabricating a stacked nanographene structure which is assembled into quantum wires or ribbons. While it has been demonstrated that nanowires can be fabricated from various raw carbon materials including PAHs, research and industry has not produced a self-assembled nanowire produced from asphaltene materials that exhibits a metallic character and electronic structure. The following methods and materials can be used to produce new class of materials consisting of a self-assembled quantum wire out of asphaltene.

### CROSS REFERENCE TO RELATED APPLICATIONS

This application claims priority to U.S. Provisional Application 62/730,729 filed Sep. 13, 2018, which is incorporated by reference in its entirety.

### STATEMENT REGARDING FEDERALLY FUNDED RESEARCH

None.

### BACKGROUND OF THE INVENTION

### A. Field of the Invention

The invention generally concerns nanomaterials. In particular certain embodiments are directed to methods and compositions related to quantum wires.

### B. Description of Related Art

Nanoelectronic devices are constantly seeking new materials to further scale integrated circuits applications. Potential candidates for new materials must eventually achieve the highest possible density integration in combination with high ballistic conductance, high thermal conductivity, and high current density. These new materials will be able to outperform silicon, the material currently used to fabricate semiconductors. For example, the charge carrier density in a sub-10 nm Field Effect Transistor (FET) is four times higher in Carbon Nanotubes (CNTs) than for silicon-based devices after normalizing for diameter. The current market barrier for these materials is in part due to the difficulty in producing and purifying exclusively semi-conducting or metallic states. Metallic CNTs and graphenes are potential candidates for the on-chip interconnect materials in future integrated circuits because they have potential advantages for achieving the highest possible density integration in combination with ballistic conductance, high thermal conductivity, and high current density.

### SUMMARY OF THE INVENTION

The inventors have discovered a high performance, low-cost, solution processed, metallic, self-assembled columnar molecular wire for use as low resistance contacts in CNT or graphene based devices. Embodiments of the current invention provide a solution to the difficulties associated with producing metallic CNTs and graphenes. In particular, the inventors have developed an inexpensive ohmic nanocarbon material (ohmic materials are those materials for which Ohm's law (V=IR) holds true), which will enable smaller devices with less carrier scattering and thus higher energy efficiency. This novel nanocarbon material can be deposited from solution and is an attractive alternative for top down deposition of metallic nanowires and interconnects with low-temperature ballistic transport with higher thermal/oxidative stability than currently used metals (i.e., copper).

The present disclosure is related to a method of fabricating a stacked nanographene structure which is assembled into quantum wires or ribbons. While it has been demonstrated that nanowires can be fabricated from various raw carbon materials including PAHs, research and industry has not produced a self-assembled nanowire produced from asphaltene materials that exhibits a metallic character and electronic structure. Asphaltenes are molecular substances that are found in crude oil, along with resins, aromatic hydrocarbons, and saturates. Asphaltenes consist primarily of carbon, hydrogen, nitrogen, oxygen, and sulfur, as well as trace amounts of vanadium and nickel. The C:H ratio is approximately 1:1.2, depending on the asphaltene source. Asphaltenes are defined operationally as the n-heptane insoluble, toluene-soluble component of a carbonaceous material such as crude oil, bitumen, or coal. Asphaltenes have been shown to have a distribution of molecular masses in the range of 400 to 1500, but the average and maximum values are difficult to determine due to aggregation of the molecules in solution. The methods and materials described herein can be used to produce a new class of materials consisting of a self-assembled quantum wire out of asphaltene.

Asphaltene mesophase that is thermally treated in the absence of air is capable of self-assembling into one dimensional columnar nanowires due to the alignment of stacked aromatic cores. The inventors show that this thermal treatment contributes to a large increase in conductivity in the sample due to the loss of insulating hydrogen groups, the increase in sp2 hybridization and the stacking of aromatic cores. Density Functional Theory (DTF) simulations of the structure predict this behavior and explain the materials conductivity with increasing a continuous density of states at the Fermi energy. This material shows potential for use in nanowires and molecular electronics as the inventors were also able to predict that the structure has a larger number of states available at the Fermi level near conduction states than single layer graphene. It represents a class of carbon conductors that rivals current state of the art nanocarbon materials in part because of advantageous metallic properties but also its low cost self-assembly and cheap carbon precursor feedstock, asphaltene.

Certain embodiments are directed to methods of producing a one-dimensional self-assembled molecular wire. The method comprises thermally activating asphaltene. Depositing a dilute thermally activated asphaltene solution on a target location of a substrate under conditions for molecular wire self-assembly. In certain aspects, the molecular wire is formed by drop-casting. The thermally activated asphaltene solution can include an aromatic based solvent, such as chlorobenzene or the like. In certain aspects, the dilute thermally activated asphaltene solution includes 0.001, 0.005, 0.01, 0.05 to 0.5 mg/ml thermally activated asphaltene, including all values and ranges there between. In particular aspects, the dilute thermally activated asphaltene solution is or is about 0.005 mg/ml thermally activated asphaltene. The thermally activation method of asphaltene can include heating asphaltene, such as precursor discotic liquid crystals in an inert environment, such as in the absence of air. In certain aspects, the asphaltene, precursor discotic liquid crystals are heated to 350, 400, 450, 500, 550, to 600° C. In particular aspects, the asphaltene, precursor discotic liquid crystals are heated to about 500° C. The asphaltene, precursor discotic liquid crystals can be heated for 1, 5, 10, 15, 20, 25, 30, 35, 40, 45, 50, 55, to 60 minutes. In particular aspects, the asphaltene, precursor discotic liquid crystals are heated for about 10 minutes. In certain aspects the asphaltene, precursor discotic liquid crystals are produced from mesophase pitch by (a) extracting crude oil with n-alkane; (b) filtering the n-alkane; (c) dissolving the retentate in toluene forming a toluene solution; (d) filtering the toluene solution; (e) evaporating the toluene; and (f) collecting the residual asphaltene precursor discotic liquid crystals. In some aspects, the thermally activated asphaltene can contain multi-layer nanographene (MLNG). The asphaltene can be dissolved in an aromatic solvent, such as chlorobenzene or the like.

Certain embodiments are directed to a self-assembled molecular wire produced by the method(s) described herein, wherein the self-assembled molecular wires have a length of 2 to 100 microns. In certain aspects the self-assembled molecular wire has an average height of 5, 10, 15, 20, 25, 30, 35, 40, 45, 50, 55, 60, 65, 70, 75, 80, 85, 90, or 95 nm, but does not exceed 100 nm. In particular aspects the self-assembled molecular wire has an average height of 5, 10, 15, to 20 nm, in certain alternative 10 nm. The self-assembled molecular wire exhibits quantum confinement.

Other embodiments of the invention are discussed throughout this application. Any embodiment discussed with respect to one aspect of the invention applies to other aspects of the invention as well and vice versa. Each embodiment described herein is understood to be embodiments of the invention that are applicable to all aspects of the invention. It is contemplated that any embodiment discussed herein can be implemented with respect to any method or composition of the invention, and vice versa.

The term “quantum wire” refers to an electrically conducting wire in which quantum effects influence transport properties and is a one-dimensional nanowire limited to be nanosized in two directions of three spatial dimensions.

The use of the word “a” or “an” when used in conjunction with the term “comprising” in the claims and/or the specification may mean “one,” but it is also consistent with the meaning of “one or more,” “at least one,” and “one or more than one.”

The term “about” or “approximately” are defined as being close to as understood by one of ordinary skill in the art. In one non-limiting embodiment the terms are defined to be within 10%, preferably within 5%, more preferably within 1%, and most preferably within 0.5%.

The term “substantially” and its variations are defined to include ranges within 10%, within 5%, within 1%, or within 0.5%.

The terms “wt. %,” “vol. %,” or “mol. %” refers to a weight, volume, or molar percentage of a component, respectively, based on the total weight, the total volume, or the total moles of material that includes the component. In a non-limiting example, 10 moles of component in 100 moles of the material is 10 mol. % of component.

The use of the term “or” in the claims is used to mean “and/or” unless explicitly indicated to refer to alternatives only or the alternatives are mutually exclusive, although the disclosure supports a definition that refers to only alternatives and “and/or.”

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The compositions and methods of making and using the same of the present invention can “comprise,” “consist essentially of,” or “consist of” particular ingredients, components, blends, method steps, etc., disclosed throughout the specification.

Other objects, features and advantages of the present invention will become apparent from the following detailed description. It should be understood, however, that the detailed description and the specific examples, while indicating specific embodiments of the invention, are given by way of illustration only, since various changes and modifications within the spirit and scope of the invention will become apparent to those skilled in the art from this detailed description.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of the specification embodiments presented herein.

FIGS. 1A-D. Top (1A) and side view (1B) of asphaltene DLC molecules modeled using DFT with intermolecular interactions. Extracted asphaltene solids (1C). Thermal processing of Asphaltene into a Multi-layer nanographene (1D).

FIGS. 2A-F. Fourier Transform Infrared Spectroscopy of asphaltene (2A), self-assembled nanowires from heat treated asphaltene sample (2B), X Ray Diffraction patterns from asphaltene (2C) and self-assembled nanowires from heat treated asphaltene (2D) and Raman spectroscopy of asphaltene (2E) and self-assembled nanowires from heat treated asphaltene (2F).

FIGS. 3A-D. Density Functional Theory calculation of Density of States (3A) for simulated structure (3B) and showing the Fermi Energy at 0 eV (dotted line). Calculation of DOS for stacked structure in compared with single layer nano-graphene (3C) and calculated DOS for stacked structure compared with single layer graphene (3D).

FIGS. 4A-D. Scanning Tunneling Spectroscopy I-V spectra (4A) of Highly Ordered Pyrolytic Graphite (HOPG) substrate compared with asphaltene precursor and asphaltene heat treated asphaltene. The blue line is the I-V spectrum of bare graphite. The straight red line is the I-V spectrum of the heat treated sample and black line represents the I-V spectrum of the precursor sample indicating that it is less conductive than graphite. Insert (4B) shows the conductance plots (dI/dV) plots obtained from STS data for MLNG and asphaltene. Atomic Force Microscope 3-D (4C) and 1-D image (4D) of self-assembled micron length nanowires wires from MLNG sample on HOPG with 2-D height topography (inset).

FIGS. 5A-B. SEM images of micro-probe taken from points along a quantum wire from self-assembled asphaltene on the surface of copper with Voltage-Current measurements from corresponding points on quantum wire as well as the surface of the copper substrate (5A) PDOS plots for Copper cell (A) and for the simulated Nanographene on Copper (5B) where the dotted blue line represents the Fermi energy.

FIGS. 6A-B. EDX spectra of asphaltene and thermally treated asphaltene on SiO₂ (6A), with corresponding SEM image (6B) and measurement location from thermally treated asphaltene on SiO₂.

### DETAILED DESCRIPTION OF THE INVENTION

The realization of functioning high performance electronic and optoelectronic devices based on nanomaterials, in general, is impacted significantly by the electrical connections, wires and interconnects that link nanomaterials with external circuitry. One dimensional molecular wires described here in can be produced and used to provide electrical connections and interconnects between nanomaterials and other circuitry components.

Thermal treatment of asphaltene, precursor discotic liquid crystals (DLC) results in self assembles into a one dimensional columnar multi-layer nanographene due to the alignment of stacked aromatic cores and when deposited from dilute solutions further self-assemble into molecular nanowire. Without being bound of theory, it is believed that due to the loss of insulating hydrogen groups, the increase in sp² hybridization and the stacking of aromatic cores, the thermal treatment contributes to a large increase in conductivity. Discotic liquid crystals precursors are mesophases formed from disc-shaped molecules known as “discotic mesogens”. These phases are also referred to as columnar phases. Discotic mesogens are typically composed of an aromatic core surrounded by flexible alkyl chains. The aromatic cores allow charge transfer in the stacking direction through the π conjugate systems. The charge transfer allows the discotic liquid crystals or molecular wires produce from DLCs to be electrically semi-conductive along the stacking direction. Self-assembled nanowires microns in length (1 to 100 μm) may be fabricated from a dilute thermally activated asphaltene solution where the solvent is aromatic. These nanowires exhibit quantum confinement and range in height between 3 nm to 20 nm, and in certain aspects on average about 10 nm in height. These quantum confinements result in a conductive electronic state and ohmic properties are observed from these structures. In certain aspects the nanowires have a resistance on the same order or lower than that of copper.

### EXAMPLES

The following examples as well as the figures are included to demonstrate preferred embodiments of the invention. It should be appreciated by those of skill in the art that the techniques disclosed in the examples or figures represent techniques discovered by the inventors to function well in the practice of the invention, and thus can be considered to constitute preferred modes for its practice. However, those of skill in the art should, in light of the present disclosure, appreciate that many changes can be made in the specific embodiments which are disclosed and still obtain a like or similar result without departing from the spirit and scope of the invention.

### Example 1

### A. Materials and Methods

Synthesis:

Asphaltene mesophase pitch was used as the precursor discotic liquid crystal (DLC) and was extracted from Crude oil (Mayan) by n-alkane (1:40 v/v). The solution was mixed for 24 hours and filtered (Whatman 40). The retentate was dissolved in toluene and filtered again and the solution was collected and evaporated. 100 mg of sample was heated to 500° C. in the absence of air for 10 minutes in a flask using Schlenk technique and kept under vacuum.

Nanowire Fabrication:

After thermal treatment, dilute solutions of samples in chlorobenzene (5 μg/ml) were drop coated onto various substrates (Cu, Highly Ordered Pyrolytic Graphite, SiO₂/Si) and nanowires self-assemble on the surface of substrates. Drop coating is the deposition of a volume of material in solution, after which the solvent is evaporated depositing the material at the location of deposition.

Characterization:

Fourier Transform Infrared (FTIR) was taken of samples in KBr pellets (Nicolet, Thermo Scientific). X-Ray Diffraction was taken from 10-60° using Cu K_{αλ}=0.154 nm at a 0.01 scan step (Bruker). Scanning Electron Microscopy was taken of solutions on SiO₂/Si (S-4800, Hitachi). Transmission Electron Microscopy (H-7650, Hitachi, Japan) was performed after drop casting samples on lacy carbon grids. Scanning Probe Microscopy/Scanning Tunneling Spectroscopy (NT-MDT) was performed with Pt/Ir tips (DPT-10, Bruker) on Highly Ordered Pyrolytic Graphite substrates by drop coating solutions (0.05 mg/ml) from chlorobenzene (Sigma). Each sample was applied three times independently and measurements were taken of across a line one micron in length with 10 points and cycled for 5 five minutes to ensure a stable scan. Two point probe measurements were taken using an Omnicron instrument with Tungsten STM probes which were annealed prior to experimentation to remove native oxide.

Molecular modeling: Simulations were carried out using modules available in Materials Studio v. 7.0, distributed by BIOVIA. The proposed structure was built imbedded within an otherwise empty simple cubic cell of lattice parameter 30 Å (in order to approximate a molecular model when using periodic DFT algorithms). The structure geometry was as an initial approximation optimized using a Forcite force field minimization with a universal force field. The structure's geometry was further optimized via a DFT method (CASTEP), using a Generalized Gradient Approximation (GGA) with a WC functional (Wu and Cohen, 2006). The electronic Hamiltonian used an energy cutoff of 240.0 eV, a Self-Consistent Field (SCF) tolerance of 2.0×10-6 eV/atom, a 1×1×1 Monkhorst-Pack grid for Brillouin zone k-point sampling, and an ultrasoft pseudopotential. After optimizing the geometry of the structure, electronic Density of States (DOS) and band structure were calculated using an energy band tolerance of 1.0×10-5 eV, as well as the same electronic parameters as were used for the geometry optimization of the structure

### B. Results

During the heat treatment of the asphaltene, precursor DLC, cyclodehydrogenation occurs and as a result sp³ hybridized carbon atom is converted to sp² carbon. As evidenced by Fourier Transform Infrared (FTIR) spectroscopy and X-Ray Diffraction (XRD), that the structure of the asphaltene is significantly changed by the thermal treatment and can be realized as a stacked sp² hybridized carbon structure after the removal of alkyl side chain from the precursor and the rearrangement or stacking of polycyclic asphaltene molecules.

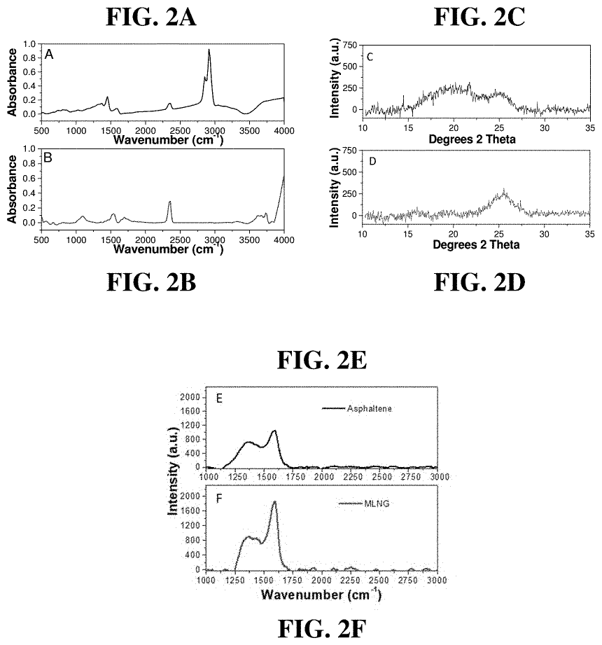

In the asphaltene, DLC precursor (FIG. 2.A), sp³ carbons are present as there are strong C—H vibration at 1400 cm⁻¹ in the FTIR spectra representing alkyl groups. Also there is a C—H stretching vibration is observed at 2960 cm⁻¹ from hydrogen or methyl groups attached to aromatics.

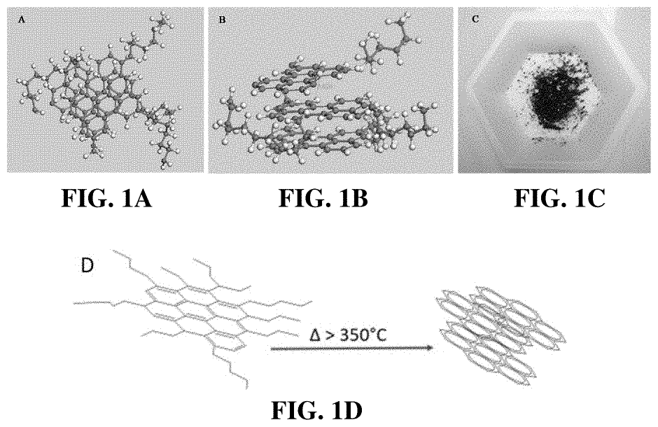

After heat treatment (FIG. 2B), the MLNG containing DLC sample shows IR-vibrational bands originated from hydrogens atoms attached to carbons via double bonds at around 1100 cm⁻¹, more C═C bond stretching at 1600 cm⁻¹ and the total absence of hydrogen attached to aromatic groups. The crystallinity of both the asphaltene and the thermally treated asphaltene, i.e. MLNG sample has been studied using X-ray powder diffraction (XRD) technique as seen in FIGS. 1C and 1D respectively. XRD confirms the presence of alkyl side chains presented by FTIR in the asphaltene. Asphaltene shows the diffraction peaks having 2-theta at around 24.5° 2 which originates from the graphitic (002) plane and another broad peak at 2-theta of 20° representing the alkyl side chains on the asphaltenes (FIG. 2C). XRD data shows that thermal treatment of the asphaltene led to a crystalline structure with d-spacing ˜3.35 Å intrinsic to π-orbital overlapping between aromatic cores along with the removal of alkyl side chains in the final product (FIG. 2D).

Raman spectroscopy was performed shows that both asphaltene (FIG. 2E) and as-synthesized MLNG (FIG. 2F) show D and G bands at around 1350 cm⁻¹ and 1584 cm⁻¹, which signifies the presence of graphitized carbon like structures. The G band corresponds to the hexagonal crystal symmetry of graphitic crystal (J. Chem. Phys., 53, 1126-1130, 1970) structure and originates from sp² hybridized carbon atoms whereas the D band is due to sp³ C—C stretching vibration. Interestingly, the MLNG shows increase in G band Raman intensity compared to asphaltene and this clearly indicates the increase in sp² carbon atoms due to increased π-π stacking structures of graphitic layers. The ratio of the intensity of G and D bands can be used to estimate the aromatic dimension (La) of both precursor and heat-treated sample according to the Tuinstra and Koenig equation La=4.4×I_{G}/I_{D} (J. Chem. Phys., 53, 1126-1130, 1970). So, the MLNG reveals higher La vale (9.16 nm) compared to that (6.16 nm) of precursor asphaltene. It is evident from the Raman and the XRD that heat-treatment has the ability to produce organized stacked multi-layer nanographene structures. In addition, after heat-treatment the D band is sufficiently broadened and distorted which is most likely due to the self-assembly of individual graphene layers stacking, resulting in the increased π-orbital overlapping in the multi-layer nanographene.

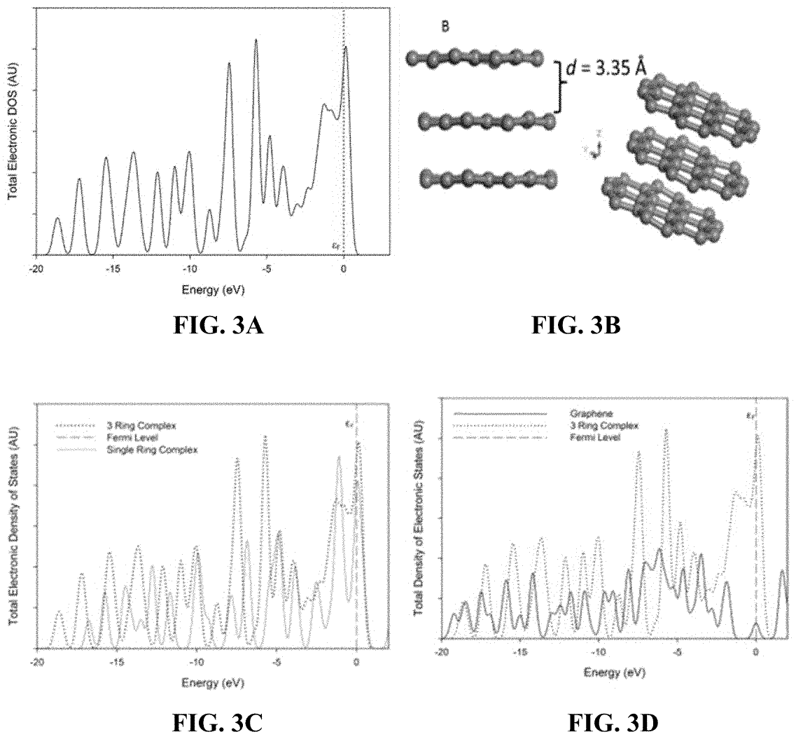

A nanographene tri-layer single stack was used as the simulated structure (FIG. 3B). The optimized minimum energy state of the structure reveals 3.35 Å as inter-layer spacing that is fundamentally characteristic of stacked aromatic cores. The total electronic Density of States (DOS) as calculated from the simulation has a large number of states available at or near the Fermi level that remains continuous with no energy gaps near conduction states (FIG. 3A) and would be expected to exhibit metallic behavior as a band gap is not evident in the DOS. Further analysis was performed to compare this simulation to a single ring structure which represents a quantum dot (FIG. 3C) and also single layer graphene (FIG. 3D). The model indicates that this structure has potential to outperform the quantum nano-graphene carbon dot and single layer graphene as the DOS remains higher in overall volume and peak intensity. In stacked ABA multilayers (Bernal Stacked), the n low-energy conduction bands are bilayer-like for an even number of layers (N=2n), but with different effective masses. In an odd number of layers (N=2n+1) a linear band with the same slope as the energy band in monolayer graphene exists next to the n parabolic ones (Koshino and McCann, Phys. Rev. B 81, 115315, 2010). Staking layers of graphene does not lead to graphite immediately and when the number of layers is sufficiently small enough, it can preserve the 2-D nature of the system (Physical Review B, 88, 115414, 2013). The valence bands can be related to the conduction bands by particle-hole symmetry.

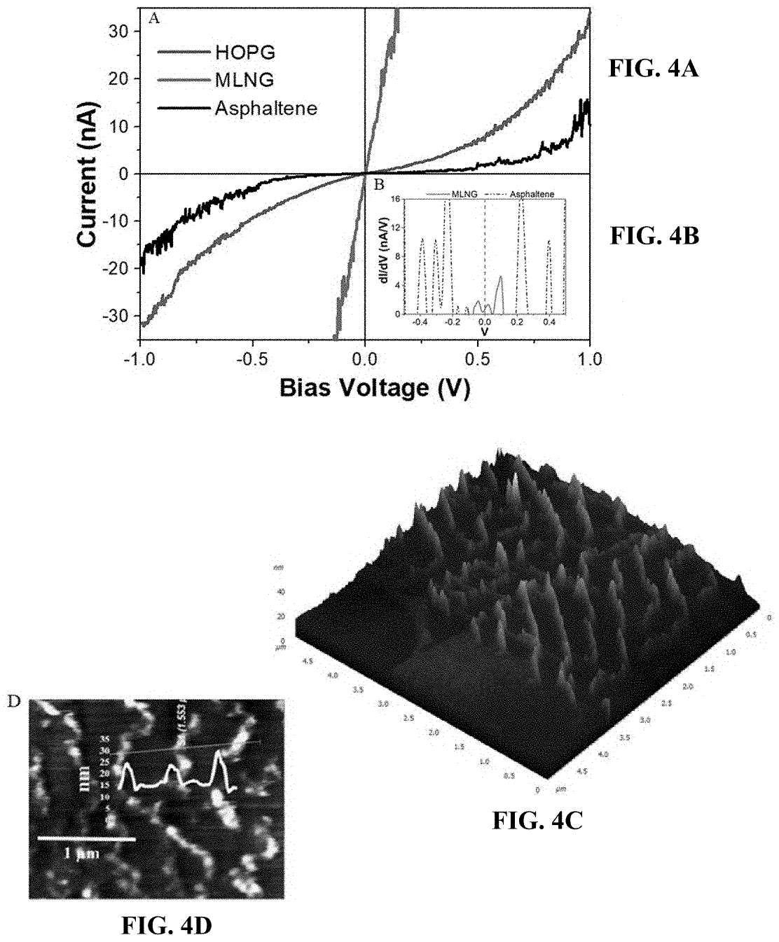

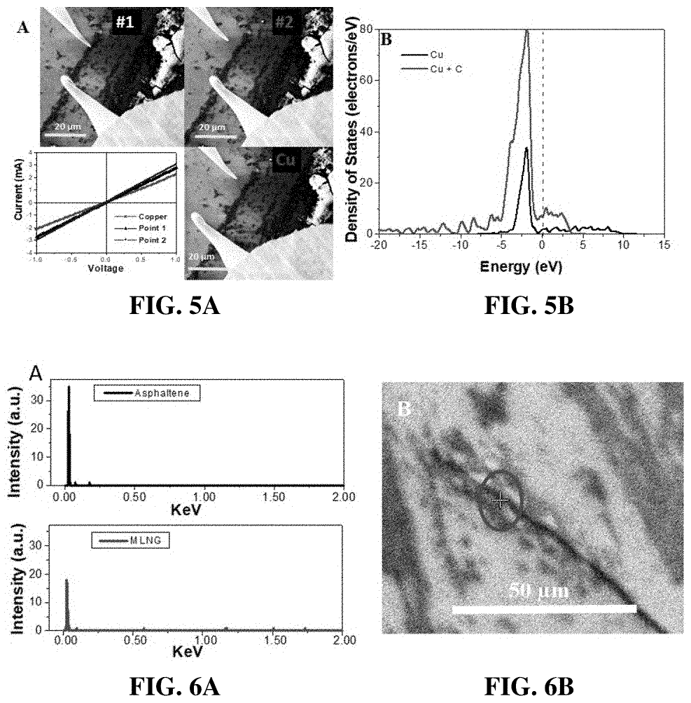

FIG. 4 and FIG. 5 show images of the self-assembled quantum wire on graphite and copper. These images from Transmission Electron Microscope, Scanning Electron Microscope and Atomic Force Microscopy illustrate the consistent self-assembly of the thermally treated asphaltenes. Voltage Current spectroscopy performed using Scanning Tunneling Spectroscopy is done without introducing contacts to the nanomaterial as it uses tunneling effect to probe the materials electronic states.

Images taken using Transmission Electron Microscope (TEM) indicate the asphaltene comprise of molecules that are spherical with sizes ranging from 10-100 nanometers which lack any formal organization. After thermal processing, the dilute solutions of MLNG remarkably self-assemble into highly ordered nanowires that appear similar to nanoribbons or nanotubes can be seen in TEM images. Scanning Electron Microscope (SEM) images of the precursor and heat treated asphaltene prepared on SiO₂/Si wafers reveal the structure of the asphaltene to appear spherical with large dendritic structures which exemplifies the discotic PAH properties associated with having aromatic cores attached to alkyl chains (J. Chem. Phys. 53, 1126-1130, 1970; Phys. Rev. B. 81, 115315 2010). However, images after thermal treatment show that the MLNG sample formed nanowires consistent with TEM analysis (Fuel, 87, 3481-3482, 2008). They show a remarkable linear organization microns in length and demonstrate an ability to form nanowires from self-assembled 1-D stacks fabricated from asphaltene.

To characterize the electronic structure of the MLNG compared to that of the asphaltene at a nanoscale molecular domain, Scanning Tunneling spectroscopy (STS) was performed for both samples on highly ordered pyrolytic graphite (HOPG) in air. Scans were taken using multiple HOPG substrates with up to 5000 scans per sample over areas 1 micron in length. FIG. 4 in particular demonstrates the difference in electronic states between asphaltene, graphite and the novel nanowire. FIG. 4A shows the current-voltage characterization of the samples as obtained by this method and is shown together with conductance (dI/dV) curves (FIG. 4B). Due to the fact that the spectra were obtained in air, surface contamination could account for some scattering between data points however, a correlation is very evident despite electronic noise. Remarkably, the MLNG sample i.e. the thermally activated asphaltene shows linear I-V curve which is indicative of an ohmic electronic state and is generally described as ohmic conduction in metals. This metal-like ohmic conductivity of the MLNG sample is consistent with the predicted behavior as already obtained by DFT analysis. Graphite clearly exhibits the semi-conducting electronic state illustrated by a curved I-V spectra. This curve represents a band-gap. Compared to the bare HOPG substrate, the asphaltene was much less conductive and behaves as an insulator, consistent with previously reported STS analysis of asphaltene (Ind. Eng. Chem. Res., 33, 2358-2363, 199 4). Clearly the insulating nature of asphaltenes is a result of aliphatic chains attached to the asphaltene aromatic cores and by removing those chains using thermal treatments, the utility of the alignment and self-association of these asphaltene molecules is demonstrated.

Further analysis on the conductive nature of thermally treated asphaltene was done using a nano-scale two-point-probe (FIG. 5). IV spectra were collected from several points along a quantum wire fabricated on copper foil using tungsten probes which were annealed to remove the native oxide. The voltage was swept from −1V to +1V and five repeat spectra were taken at each point and averaged. It can clearly be seen that the IV curves are ohmic in nature from each point collected, this is in agreement with the STS presented earlier. It can also be seen that the resistance of the wires are of the same order as the copper foil. It is usual to expect the resistance to scale with probe separation, this trend is not observed which we attribute to inconsistent contacts caused by surface contamination.

Surface scattering is an influential occurrence after the miniaturization of devices and interconnects (Solid State Physics, Elsevier Science, 1985; Phys. Rev. B., 74, 085109, 2006) whereby electrons undergo either elastic or inelastic scattering depending on the local surface states. Furthermore, the surface electron density located near the nanowire surface makes a large contribution to the total conduction electron density. In FIG. 5A, it can be seen this phenomenon occurring at the interface of the Cu and the MLNG self-assembled nanowire. While the structure is too large to contribute to tunneling, simulations show that sp² carbon does contribute states to the copper at the Fermi energy (FIG. 5B). Therefore, these surface states demonstrate an influential role in the electrical conductivity of Cu on the nanometer scale. Comparing the partial density of states (PDOS) of nanographene on Cu with the PDOS of pristine Cu, new states present around the Fermi Energy in the simulation of Cu with NG are due to the interaction between Cu 3d electrons and the C 2p electrons. Simulations of the surfaces provides further explanation of electronic behavior and thus electron transport at the interface. These findings are supported by previous theoretical investigations performed on a contact configuration simulated by a metallic single wall carbon nanotube and linear copper chain (Phys. Rev. B., 60, 6074-6079, 1999). Cu atoms positioned in front of the CNT's carbon atom significantly influence the electronic properties of the entire hybrid system. Moreover, the hybrid system was shown to induce a sizeable charge transfer from the Cu 4s and 3d states to the C atom of the tube. Therefore, a higher number of electronic states are made available, thus increasing the systems total DOS compared pristine Cu or C alone. Studies performed on Cu nanoclusters on ziz-zag graphene nanoribons have also revealed the same hybridization of p and d orbitals between C and Cu in DOS simulations (J. Comput. Electron., 14, 270-279, 2015). An additional study on the impact these effects have on the transport of the nanoribbons determined that copper can alter the current-voltage characteristics and create a negative differential resistance (J. Appl. Phys., 116, 093701, 2014).

Electron Dispersion X-ray (EDX) Elemental analysis shows both the starting material and the novel product to be made up of only carbon and no other elements in FIG. 6.

1. Method of producing a one-dimensional self-assembled molecular wire comprising depositing a dilute thermally activated asphaltene solution on a target location of a substrate under conditions for molecular wire self-assembly.

2. The method of claim 1, where molecular wire is formed by drop-coating.

3. The method of claim 1, wherein the asphaltene solution comprises an aromatic based solvent.

4. The method of claim 3, wherein the aromatic based solvent is chlorobenzene.

5. The method of claim 1, wherein the dilute asphaltene solution comprises 0.001, 0.005, 0.01, 0.05 to 0.5 mg/ml asphaltene.

6. The method of claim 1, wherein the dilute asphaltene solution comprises 0.005 mg/ml asphaltene.

7. The method of claim 1, the thermally activated asphaltene is prepared by heating asphaltene in the absence of air.

8. The method of claim 7, wherein the asphaltene discotic liquid crystals are heated to 350 to 600° C.

9. The method of claim 7, wherein the asphaltene discotic liquid crystals are heated to about 500° C.

10. The method of claim 7, wherein the asphaltene is heated for 1 to 60 minutes.

11. The method of claim 7, wherein the asphaltene is heated for about 10 minutes.

12. The method of claim 7, wherein the asphaltene are produced from mesophase pitch by (a) extracting crude oil with n-alkane; (b) filtering the n-alkane; (c) dissolving the retentate in toluene forming a toluene solution; (d) filtering the toluene solution; (e) evaporating the toluene; and (f) collecting the residual asphaltene.

13. The method of claim 1, wherein the asphaltene is dissolved in an aromatic solvent.

14. The method of claim 13, wherein the aromatic solvent is toluene or chlorobenzene.

15. A self-assembled molecular wire produced by the method of claim 1, wherein the self-assembled molecular wires have a length of 2 to 100 microns.

16. The self-assembled molecular wire of claim 15, wherein the wire has a height of 10 nm.

17. The self-assembled molecular wire of claim 16, wherein the wire exhibits quantum confinement.
